(19) United States
(12) Patent Application Publication
(10) Pub. No.: US 2011/0250755 A1
(43) Pub. Date: Oct. 13, 2011

(54) METHOD OF POLISHING WAFER SURFACE ON WHICH COPPER AND SILICON ARE EXPOSED

(75) Inventors: Hitoshi MORINAGA, Ichinomiya-shi (JP); Noboru YASUFUKU, Ichinomiya-shi (JP); Toshio SHINODA, Kakamigahara-shi (JP)

(73) Assignee: FUJIMI INCORPORATED, Kiyosu-shi (JP)

(21) Appl. No.: 13/080,215

(22) Filed: Apr. 5, 2011

(30) Foreign Application Priority Data
Apr. 8, 2010 (JP) 2010-089695

(51) Int. Cl. H01L 21/306

(52) U.S. Cl. 438/693; 257/E21.23

(57) ABSTRACT

A method of the present invention includes polishing a wafer having an exposed copper or copper alloy surface and an exposed silicon surface by using a polishing composition containing 0.02 to 0.6% by mass of hydrogen peroxide, preferably 0.05 to 0.2% by mass thereof. The polishing composition preferably further contains at least one of a complexing agent, an inorganic electrolyte, and abrasive grains such as colloidal silica. The polishing composition has a pH of preferably 9 or more, more preferably 10 or more.

### BACKGROUND OF THE INVENTION

The present invention relates to a method of polishing a wafer surface on which copper and silicon are exposed, that is, a wafer having an exposed copper or copper alloy surface and an exposed silicon surface.

For a manufacturing process of semiconductor devices in recent years, there is a requirement for simultaneously polishing copper or a copper alloy, which is a wiring material, and silicon, which is a semiconductor material, specifically a requirement for polishing a wafer having an exposed copper or copper alloy surface and an exposed silicon surface. However, when such a wafer is polished, there is a problem of contaminating the wafer with copper by the diffusion of copper atoms to the inner part of the wafer through the exposed silicon surface.

As described, for example, in Japanese Laid-Open Patent Publication No. 63-272460, metal is liable to adsorb to the surface of a silicon wafer that is being polished, and there is a problem that the adsorbed metal diffuses to the inner part of the silicon wafer and degrades the electric characteristics of a semiconductor device. Further, metal atoms are liable to adhere to the surface of a silicon wafer in an alkaline solution as described, for example, in Japanese Laid-Open Patent Publication No. 2002-226836. Metal atoms, particularly copper atoms, which have a large diffusion coefficient, adhered to the surface of a silicon wafer easily diffuse to the inner part of the silicon wafer at room temperature or a temperature during polishing (30° C. to 50° C.).

Japanese Laid-Open Patent Publication Nos. 63-272460 and 2002-226836 disclose polishing compositions that are improved to prevent metal contamination of silicon wafers. The polishing compositions disclosed in Japanese Laid-Open Patent Publication Nos. 63-272460 and 2002-226836 each contain a chelating agent that forms a complex with metal atoms in the polishing composition to capture the metal atoms, thereby suppressing the adsorption of the metal atoms on a silicon wafer. However, in the case of polishing a wafer having an exposed copper or copper alloy surface and an exposed silicon surface, a large amount of copper atoms is liberated through the polishing of the copper or copper alloy surface. Therefore, the use of the polishing compositions disclosed in Japanese Laid-Open Patent Publication Nos. 63-272460 and 2002-226836 is not sufficient to prevent the copper contamination of a wafer caused by the adsorption of copper atoms on an exposed silicon surface.

### SUMMARY OF THE INVENTION

Accordingly, it is an objective of the present invention to provide a method capable of preventing copper contamination that may occur during polishing of a wafer having an exposed copper or copper alloy surface and an exposed silicon surface.

To achieve the foregoing objective, one aspect of the present invention provides a method of polishing a wafer having an exposed copper or copper alloy surface and an exposed silicon surface by using a polishing composition containing 0.02 to 0.6% by mass of hydrogen peroxide, preferably 0.05 to 0.2% by mass thereof.

The polishing composition preferably further contains at least one of a complexing agent, an inorganic electrolyte, and abrasive grains such as colloidal silica. Further, the polishing composition has a pH of preferably 9 or more, more preferably 10 or more.

### BRIEF DESCRIPTION OF THE DRAWINGS

FIG. 1(a) is a cross-sectional view showing the surface of a wafer before polishing by a polishing method according to one embodiment of the present invention; and

FIG. 1(b) is a cross-sectional view showing an example of the surface of a wafer after polishing by a polishing method according to one embodiment of the present invention.

### DETAILED DESCRIPTION OF THE PREFERRED EMBODIMENTS

Hereinafter, one embodiment of the present invention will be described.

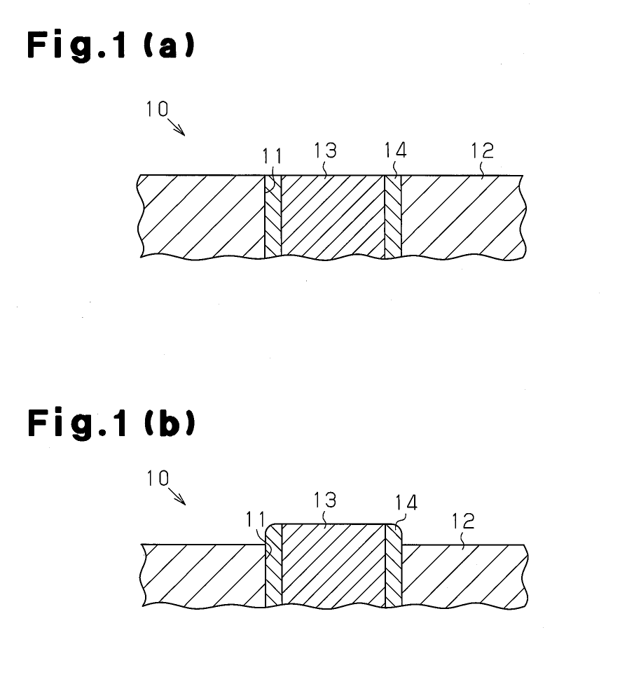

In a polishing method of the present embodiment, a wafer having an exposed copper or copper alloy surface and an exposed silicon surface is subjected to chemical mechanical polishing using a polishing composition. A wafer 10 shown in FIG. 1(a) comprises a silicon substrate 12 having a via 11 and a conductor 13 composed of copper or a copper alloy with which the via 11 is filled. The wafer 10 has an exposed copper or copper alloy surface and an exposed silicon surface. A barrier metal film 14 is provided on the surface defining the via 11 and prevents the diffusion of copper atoms of the conductor 13 to the silicon substrate 12. The barrier metal film 14 is formed, for example, from tantalum, tantalum nitride, or titanium nitride.

The chemical mechanical polishing of a wafer having an exposed copper or copper alloy surface and an exposed silicon surface is performed, for example, for planarizing the surface of the wafer or relieving stress of the wafer by polishing both of the copper or copper alloy surface and the silicon surface, or for forming a protrusion mainly composed of copper or a copper alloy on the surface of the wafer, as shown for example in FIG. 1(b), by mainly polishing the silicon surface. However, the shape of the surface of the wafer after polishing is not limited to that shown in FIG. 1(b).

Such chemical mechanical polishing can be performed using a general polishing device having a surface plate to which a polishing pad is adhered.

The polishing pressure when a wafer is subjected to chemical mechanical polishing, that is, the contact pressure of the polishing pad to a wafer is preferably 3 to 100 kPa, more preferably 10 to 40 kPa.

The rotational rate of the surface plate when a wafer is subjected to chemical mechanical polishing is preferably 20 to 1000 rpm, more preferably 40 to 500 rpm.

The amount of a polishing composition fed to the polishing pad when a wafer is subjected to chemical mechanical polishing, that is, the feed rate of a polishing composition, is preferably 50 to 2000 mL/min, more preferably 100 to 500 mL/min.

The polishing composition used when a wafer is subjected to chemical mechanical polishing contains 0.02 to 0.6% by mass of hydrogen peroxide. When the content of hydrogen peroxide in the polishing composition is less than 0.02% by mass, it is difficult to suppress copper contamination of a wafer to a practical level. In order to suppress copper contamination of a wafer to a level particularly suitable for practical use, the content of hydrogen peroxide in the polishing composition is preferably 0.03% by mass or more, more preferably 0.05% by mass or more. On the other hand, when the content of hydrogen peroxide in the polishing composition exceeds 0.6% by mass, it will be difficult to obtain a practical level of silicon removal rate. In order to obtain a level of silicon removal rate particularly suitable for practical use, the content of hydrogen peroxide in the polishing composition is preferably 0.3% by mass or less, more preferably 0.2% by mass or less.

The polishing composition preferably further contains a complexing agent that coordinates with metal to form complex ions. When the complexing agent is contained, the effect of the polishing composition in suppressing copper contamination of a wafer is improved, and the removal rate of copper or a copper alloy by the polishing composition is also improved.

Examples of donor atoms having complex-forming properties with copper atoms include a nitrogen atom, an oxygen atom, a phosphorus atom, and a halogen atom. Examples of typical ligands having these donor atoms include an amide group, a carboxyl group, a carbonyl group, an amino group, an imino group, an azo group, a hydroxy group, and a phosphonic acid group. The complexing agent to be used is not particularly limited as long as it contains at least one of these ligands in the compound. Specific examples of the complexing agent include the following compounds:

amino acids such as arginine, histidine, glycine, alanine, and asparagine;

iminocarboxylic acids such as iminodiacetic acid, nitrilotriacetic acid, ethylenediaminetetraacetic acid (EDTA for short), trans-1,2-diaminocyclohexane tetraacetic acid (CyDTA for short), diethylenetriamine pentaacetic acid (DTPA for short), triethylenetetramine hexaacetic acid (TTHA for short), 1,6-hexamethylenediamine tetraacetic acid (HDTA for short), ethylenediamine-di-ortho-hydroxyphenylacetic acid (EDDHA for short), ethylenediamine-N,N′-bis[(2-hydroxy-5-methylphenyl)acetic acid] (EDDHMA for short), and N,N-bis(2-hydroxybenzyl)ethylenediamine-N,N-diacetic acid (HBED for short);

phosphonic acids such as nitrilotris(methylene phosphonic acid) (NTMP for short), 1-hydroxyethylidene-1,1-diphosphonic acid (HEDP for short), methanehydroxyphosphonic acid, and α-methylphosphonosuccinic acid;

iminophosphonic acids such as ethylenediamine tetrakis(methylenephosphonic acid) (EDTPO for short), ethylenediamine-N,N′-bis[(2-hydroxy-5-methylphenyl)phosphonic acid], ethylenediamine-N,N′-bis[(2-hydroxy-5-phosphophenyl)phosphonic acid;

hydrazine compounds such as hydrazine and phenylhydrazine;

amines such as ethylenediamine, hexamethylenediamine, diethylenetriamine, triethylenetriamine, tetraethylenepentamine, phenylenediamine, pentamethylenehexamine, hexamethyleneheptamine, polyethyleneimine, methylamine, ethylamine, trimethylamine, triethylamine, triethanolamine, tetramethylethylenediamine, aniline, and catecholamine;

amides and imides such as carbamic acid, oxamic acid, carbanilic acid, formamide, diacetoamide, acrylamide, succinimide, maleimide, and phthalic imide;

heterocyclic amines including: pyridine compounds such as pyridine, piperidine, 3-pyridinol, isonicotinic acid, picolinic acid, acetylpyridine, 4-dimethylaminopyridine, nitropyridine, 2,4,6-tris(2-pyridyl)-1,3,5-triazine (TPTZ for short), 3-(2-pyridyl)-5,6-bis(4-sulfonyl)-1,2,4-triazine (PDTS for short), syn-phenyl-2-pyridyl ketoxime (PPKS for short); quinoline compounds such as quinoline, quinaldine, 8-quinolinol, 2-methyl-8-quinolinol, and qunaldinic acid; pyrazole compounds such as pyrazole and 5-pyrazolone; imidazole compounds such as imidazole and methylimidazole; benzimidazole compounds such as benzimidazole; diazine compounds such as diazine, pyrimidine, and pyrazine; piperazine compounds such as piperazine; benzodiazines and dibenzodiazines such as cinnoline and phenazine; triazines; purines; phenanthrolines; oxazole compounds and isoxazole compounds such as oxazole, 4-oxazolone, isoxazole, and azoxime; oxazines; thiazoles and benzothiazoles; isothiazoles; triazines; pyrroles; pyrrolines and pyrrolidines; indoles; indolines; isoindoles; carbazoles; indigos; and porphyrins;

monocarboxylic acids such as formic acid, acetic acid, propionic acid, butyric acid, isobutyric acid, decanoic acid, dodecanoic acid, benzoic acid, and phenylacetic acid;

polycarboxylic acids such as oxalic acid, malonic acid, succinic acid, maleic acid, and fumaric acid;

hydroxycarboxylic acids such as glycolic acid, gluconic acid, lactic acid, hydroxybutyric acid, hydroxyacetic acid, hydroxybenzoic acid, salicylic acid, tartronic acid, malic acid, tartaric acid, and citric acid;

phenol compounds such as phenol, cresol, catechol, and resorcinol;

aldehydes and ketones including: aliphatic aldehydes such as formaldehyde and acetaldehyde; aliphatic ketones such as acetone, ethyl methyl ketone, 3-pentanone, pinacolin, 2-heptanone, 3-heptanone, 4-heptanone, and 6-methylheptanone; ketenes; aromatic aldehydes; and aromatic ketones; and

polyoxo compounds such as glyoxal, malonaldehyde, diacetyl, acetylacetone, and pyruvic aldehyde.

An inorganic complexing agent can also be used. Specific examples of the inorganic complexing agent include: hydrogen halides such as hydrofluoric acid, hydrochloric acid, hydrogen bromide, and hydrogen iodide, and salts thereof; and oxo acids such as sulfuric acid, phosphoric acid, condensed phosphoric acid, boric acid, silicic acid, carbonic acid, nitric acid, nitrous acid, perchloric acid, chloric acid, chlorous acid, and hypochlorous acid, and salts thereof.

Generally, the content of a complexing agent in the polishing composition, which is properly set depending on the type of the complexing agent used, is preferably 10% by mass or less, more preferably in the range of 0.01% by mass or more and 5% by mass or less.

The polishing composition preferably further contains an inorganic electrolyte. When an inorganic electrolyte is contained, the removal rate of silicon by the polishing composition is improved.

The type of cation and anion produced by the dissociation of the inorganic electrolyte used is not particularly limited, and any inorganic electrolyte can be properly selected for use. For example, the cation produced by the dissociation of the inorganic electrolyte used may be an alkali metal ion such as a potassium ion and a sodium ion, or may be an alkaline earth metal ion such as a calcium ion, a magnesium ion, and a barium ion. The cation may be a non-metal ion such as an ammonium ion. However, when the influence of diffusion of cation to a wafer is taken into consideration, a potassium ion and an ammonium ion are preferred. Further, the anion produced by the dissociation of the inorganic electrolyte used may be a halogen ion such as a fluoride ion, a bromide ion, a chloride ion, a hypochlorite ion, a chlorite ion, a chlorate ion, a perchlorate ion, an iodide ion, a periodate ion, and an iodate ion, or may be a hydroxide ion, a cyanide ion, a thiocyanate ion, a nitrate ion, a nitrite ion, a sulfate ion, a hydrogen sulfate ion, a carbonate ion, a bicarbonate ion, an acetate ion, or a permanganate ion. However, when reduction of the effort needed to treat a waste polishing composition and an improvement of work environment in using a polishing composition are taken into consideration, a chloride ion, a hydroxide ion, and a carbonate ion are preferred.

The use of strong electrolytes such as potassium chloride is advantageous because an effect is obtained by using a small amount thereof.

The content of an inorganic electrolyte in the polishing composition is preferably 20% by mass or less, more preferably 15% by mass or less.

The polishing composition preferably further contains abrasive grains that have a function for mechanically polishing a wafer. Specific examples of the abrasive grains include silica such as colloidal silica, fumed silica, and sol-gel derived silica, alumina, titania, zirconia, and ceria. Colloidal silica is preferred among these abrasive grains.

The mean dispersed particle diameter of the abrasive grains used is preferably 5 to 1,000 nm, more preferably 5 to 500 nm, further preferably 10 to 200 nm.

The content of abrasive grains in the polishing composition is preferably 0.1% by mass or more, more preferably 0.5% by mass or more, further preferably 1.0% by mass or more. When the content is in the range as described above, it is easy to obtain a level of silicon removal rate particularly suitable for practical use.

The content of abrasive grains in the polishing composition is also preferably 20% by mass or less, more preferably 10% by mass or less. The dispersibility of abrasive grains in the polishing composition is improved as the content of the abrasive grains decreases.

The polishing composition has a pH of preferably 9 or more, more preferably 10 or more. The polishing composition also has a pH of preferably 13 or less, more preferably 12 or less. When the polishing composition has a pH of 9 or more and 13 or less, more specifically 10 or more and 12 or less, it is easy to obtain a level of silicon removal rate particularly suitable for practical use. A pH adjuster may be used for obtaining a desired pH. The type of the pH adjuster to be used is not particularly limited, and examples thereof include inorganic alkali compounds such as potassium hydroxide, sodium hydroxide, potassium bicarbonate, potassium carbonate, sodium bicarbonate, and sodium carbonate; ammonia; ammonium salts such as tetramethylammonium hydroxide, ammonium bicarbonate, and ammonium carbonate; and amines such as 1-(2-aminoethyl)piperazine, N-methyl piperazine, methylamine, dimethylamine, diethylamine, monoethanolamine, N-(β-aminoethyl)ethanolamine, and triethylenetetramine. Preferred are tetramethylammonium hydroxide, potassium hydroxide, sodium hydroxide, and ammonia. The amines as described above as an example of a complexing agent can also be used as a pH adjuster.

The removal rate ratio, which is obtained by dividing the removal rate of copper or a copper alloy with a polishing composition by the removal rate of silicon with the same polishing composition, is preferably 0.05 or more and 1 or less, more preferably 0.1 or more and 1 or less. The value of the removal rate ratio increases as the content of a complexing agent in the polishing composition increases.

According to the present embodiment, the following advantages are obtained.

In the polishing method of the present embodiment, a polishing composition containing 0.02 to 0.6% by mass of hydrogen peroxide is used for polishing a wafer having an exposed copper or copper alloy surface and an exposed silicon surface. In this case, the copper contamination of the wafer is suitably suppressed. The reason is assumed that the adhesion of copper atoms to the silicon surface is suppressed because copper atoms adsorbed on the silicon surface are ionized again by a function of hydrogen peroxide.

When a polishing composition further containing a complexing agent is used, the copper contamination of a wafer having an exposed copper or copper alloy surface and an exposed silicon surface is further suppressed. The reason is assumed that the adhesion of copper atoms to the silicon surface is further suppressed because copper atoms liberated by the polishing of the copper or copper alloy surface are captured by the complexing agent.

The above embodiment may be changed as follows.

The polishing composition used in the polishing method of the above embodiment may contain two or more complexing agents.

The polishing composition used in the polishing method of the above embodiment may contain two or more inorganic electrolytes.

The polishing composition used in the polishing method of the above embodiment may contain two or more types of abrasive grains.

To the polishing composition used in the polishing method of the above embodiment may be optionally added an additive such as a water-soluble polymer, a surfactant, a preservative, an antifungal agent, and an anticorrosive agent.

The polishing composition used in the polishing method of the above embodiment may be prepared by diluting a stock solution of the polishing composition with water.

The polishing composition used in the polishing method of the above embodiment may be of a one-component type or of a multi-component type such as a two-component type. For example, the polishing composition may be prepared by mixing a first component containing at least hydrogen peroxide with a second component containing at least one of a complexing agent and an inorganic electrolyte.

The chemical mechanical polishing in the polishing method of the above embodiment may be performed by feeding a polishing composition onto a polishing pad containing abrasive grains of ceria, silica, alumina, or a resin. In this case, abrasive grains need not be contained in the polishing composition to be used.

Next, Examples and Comparative Examples of the present invention will be described.

The polishing compositions of Examples 1 to 21 and Comparative Examples 1 to 5 were prepared by mixing at least one of colloidal silica (abrasive grain) having a mean primary particle diameter of 50 nm, a complexing agent, potassium chloride (inorganic electrolyte), and hydrogen peroxide with water, optionally together with tetramethylammonium hydroxide (pH adjuster). Table 1 shows the details of colloidal silica, a complexing agent, potassium chloride, and hydrogen peroxide in the polishing compositions and the results of measurement of pH of the polishing compositions. In preparing the polishing compositions, abrasive grains were provided to which was added water and optionally a pH adjuster, and then thereto was added at least one of a complexing agent, potassium chloride, and hydrogen peroxide in this order.

The “silicon removal rate” column of Table 1 shows the value of the silicon removal rate when the surface of a silicon wafer cut into a 32 mm square shape is polished with the polishing compositions of Examples 1 to 21 and Comparative Examples 1 to 5 under the conditions as described in Table 2. The value of the silicon removal rate was determined by dividing the difference in the weight of each wafer before and after polishing measured using a precision balance “AG-285” available from Mettler-Toledo International Inc. by polishing time (15 minutes).

The “copper removal rate” column of Table 1 shows the value of the copper removal rate when the surface of a 5000 Å copper blanket wafer cut into a 32 mm square shape is polished with the polishing compositions of Examples 1 to 21 and Comparative Examples 1 to 5 under the conditions as described in Table 2. The value of the copper removal rate was determined by dividing the difference in the weight of each wafer before and after polishing measured using a precision balance “AG-285” available from Mettler-Toledo International Inc. by polishing time (1 minute).

The “copper removal rate/silicon removal rate” column of Table 1 shows the value of the removal rate ratio, which is a value obtained by dividing the copper removal rate by the silicon removal rate, as determined for each of the polishing compositions of Examples 1 to 21 and Comparative Examples 1 to 5 as described above.

The “amount of copper contamination of silicon wafer” column of Table 1 shows the number of copper atoms, which are present in the silicon wafer surface layer, as measured by the procedures as described in Table 3. The number of copper atoms was determined from the mass of copper atoms as measured with an inductively coupled plasma source mass spectrometer “Agilent 4500” available from Agilent Technologies Inc.

TABLE 1

| | | | | | | | | | Copper | Amount |
|---|---|---|---|---|---|---|---|---|---|---|
| | | | | | | | Silicon | Copper | removal | of copper |
| | Colloidal | Complexing agent | | Potassium | Hydrogen | | removal | removal | rate/ | contamination |
| | silica | | Content | chloride | peroxide | | rate | rate | Silicon | of |
| | (% by | | (% by | (% by | (% by | | (μm/ | (μm/ | removal | silicon wafer |
| | mass) | Type | mass) | mass) | mass) | pH | min) | min) | rate | (atoms/cm²) |
| Ex. 1 | 8 | — | — | — | 0.150 | 10.7 | 0.24 | 0.02 | 0.07 | 5E+10 |
| Ex. 2 | 8 | Ammonium citrate | 0.04 | — | 0.150 | 11.4 | 0.29 | 0.08 | 0.28 | 5E+10 |
| Ex. 3 | 8 | — | — | 8 | 0.150 | 10.8 | 0.42 | 0.02 | 0.05 | 5E+10 |
| Ex. 4 | 8 | Alanine | 0.20 | 8 | 0.150 | 10.6 | 0.40 | 0.23 | 0.56 | 5E+10 |
| Ex. 5 | 2 | Triethylenetetramine | 0.08 | 2 | 0.150 | 10.5 | 0.40 | 0.16 | 0.40 | 5E+10 |
| Ex. 6 | 8 | Citric acid | 0.20 | 8 | 0.150 | 10.7 | 0.42 | 0.08 | 0.20 | 5E+10 |
| Ex. 7 | 2 | Citric acid | 0.10 | 2 | 0.150 | 10.8 | 0.45 | 0.07 | 0.15 | 5E+10 |
| Ex. 8 | 2 | Citric acid | 0.10 | 2 | 0.150 | 6.5 | 0.17 | 0.17 | 1.03 | 5E+10 |
| Ex. 9 | 8 | Malonic acid | 0.20 | 8 | 0.150 | 10.7 | 0.42 | 0.07 | 0.17 | 5E+10 |
| Ex. 10 | — | Ammonium citrate | 0.04 | 8 | 0.150 | 11.7 | 0.07 | 0.03 | 0.45 | 5E+10 |
| Ex. 11 | 8 | Ammonium citrate | 0.04 | 8 | 0.030 | 10.7 | 0.59 | 0.11 | 0.18 | 9E+11 |
| Ex. 12 | 8 | Ammonium citrate | 0.04 | 8 | 0.050 | 10.7 | 0.57 | 0.09 | 0.15 | 5E+10 |
| Ex. 13 | 8 | Ammonium citrate | 0.04 | 8 | 0.075 | 10.7 | 0.54 | 0.08 | 0.15 | 5E+10 |
| Ex. 14 | 8 | Ammonium citrate | 0.04 | 8 | 0.150 | 10.6 | 0.42 | 0.07 | 0.17 | 5E+10 |
| Ex. 15 | 8 | Ammonium citrate | 0.04 | 8 | 0.225 | 10.6 | 0.35 | 0.07 | 0.20 | 5E+10 |
| Ex. 16 | 8 | Ammonium citrate | 0.04 | 8 | 0.300 | 10.5 | 0.30 | 0.07 | 0.22 | 5E+10 |
| Ex. 17 | 8 | Ammonium citrate | 0.04 | 8 | 0.600 | 10.3 | 0.17 | 0.07 | 0.40 | 5E+10 |
| Ex. 18 | 2 | Ammonium citrate | 0.13 | 2 | 0.150 | 9.8 | 0.51 | 0.21 | 0.41 | 5E+10 |
| Ex. 19 | 2 | Ammonium citrate | 0.25 | 2 | 0.150 | 9.3 | 0.49 | 0.44 | 0.89 | 5E+10 |
| Ex. 20 | 2 | Ammonium citrate | 0.80 | 1 | 0.050 | 10.3 | 0.42 | 0.08 | 0.19 | 5E+10 |
| Ex. 21 | 2 | Ammonium citrate | 1.20 | 4 | 0.050 | 10.5 | 0.52 | 0.15 | 0.29 | 5E+10 |
| Com. Ex. 1 | 8 | — | — | — | — | 10.6 | 0.40 | 0.01 | 0.03 | 7E+14 |
| Com. Ex. 2 | 8 | — | — | 8 | — | 10.8 | 0.52 | 0.01 | 0.01 | 7E+14 |
| Com. Ex. 3 | 8 | Ammonium citrate | 0.04 | 8 | — | 10.7 | 0.47 | 0.04 | 0.08 | 5E+13 |
| Com. Ex. 4 | 8 | Ammonium citrate | 0.04 | 8 | 0.015 | 10.7 | 0.53 | 0.08 | 0.16 | 2E+13 |
| Com. Ex. 5 | 8 | Ammonium citrate | 0.04 | 8 | 0.800 | 10.3 | 0.09 | 0.07 | 0.69 | 5E+10 |

TABLE 2
Polishing machine: bench-type polishing machine “EJ-380IN” made by
Engis Japan Corporation
Polishing pressure: 25.1 kPa
Polishing surface plate rotational rate: 40 rpm
Polishing pad: “SUBA400” made by Nitta Haas Incorporated
Polishing composition feed rate: 50 mL/min.
Temperature of polishing composition: 25° C.

TABLE 3
Procedure 1: A surface oxide film of a silicon wafer having a diameter of
200 mm is removed by immersing it in a 3% aqueous hydrofluoric acid
solution for 3 minutes.
Procedure 2: The wafer treated in Procedure 1 is immersed for 3 minutes
in one of the polishing compositions of Examples 1 to 21 and Comparative
Examples 1 to 5 to which 1 ppm of copper is added as forced
contamination.
Procedure 3: An aqueous solution is prepared by adding hydrogen
peroxide in a concentration contained in the polishing composition to a
0.5% aqueous hydrofluoric acid solution. The wafer, which has been sub-
jected to copper contamination in Procedure 2, is immersed in the resulting
aqueous solution for 10 minutes and then washed.
Procedure 4: The metal on the wafer surface washed by Procedure 3 is
collected by a VPD (vapor phase decomposition) method using a rotating
surface collection system, and the collected metal is measured with an
“Agilent 4500.” The chemical solution used in the VPD method is an
aqueous solution containing 5% of hydrogen peroxide and 5% of
hydrofluoric acid.

As shown in Table 1, when the polishing compositions of Examples 1 to 21 each having a content of hydrogen peroxide in the range of 0.02 to 0.6% by mass were used, the amount of copper contamination of a silicon wafer was at a low level of less than 1×10¹² atoms/cm². On the other hand, when the polishing compositions of Comparative Examples 1 to 3 containing no hydrogen peroxide were used, and when the polishing composition of Comparative Example 4 having a content of hydrogen peroxide of less than 0.02% by mass was used, the amount of copper contamination of a silicon wafer was at a high level of more than 1×10¹³ atoms/cm². Further, when the polishing composition of Comparative Example 5 having a content of hydrogen peroxide of more than 0.6% by mass was used, the amount of copper contamination of a silicon wafer was at a low level, but a practical level of silicon removal rate was not obtained.

1. A method of polishing a wafer having an exposed copper or copper alloy surface and an exposed silicon surface, the method comprising:
preparing a polishing composition containing 0.02 to 0.6% by mass of hydrogen peroxide; and
using the polishing composition to polish the wafer.

2. The method according to claim 1, wherein the content of the hydrogen peroxide in the polishing composition is 0.05 to 0.2% by mass.

3. The method according to claim 1, further comprising adding a complexing agent to the polishing composition prior to said using.

4. The method according to claim 1, further comprising adding an inorganic electrolyte to the polishing composition prior to said using.

5. The method according to claim 1, wherein the polishing composition has a pH of 9 or more.

6. The method according to claim 5, wherein the pH of the polishing composition is 10 or more.

7. The method according to claim 1, further comprising adding abrasive grains to the polishing composition prior to said using.

8. The method according to claim 7, wherein the abrasive grains are silica.

9. The method according to claim 8, wherein the abrasive grains are colloidal silica.

10. The method according to claim 1, wherein the polishing composition has a removal rate ratio, which is obtained by dividing a removal rate of copper or a copper alloy with the polishing composition by a removal rate of silicon with the polishing composition, of 0.05 or more and 1 or less.

11. A method of polishing a wafer having an exposed copper or copper alloy surface and an exposed silicon surface, the method comprising:
preparing a polishing composition containing 0.02 to 0.6% by mass of hydrogen peroxide, a complexing agent, an inorganic electrolyte, and abrasive grains, wherein the polishing composition has a pH of 10 or more; and
using the polishing composition to polish the wafer.
